(19) United States
(12) Patent Application Publication
(10) Pub. No.: US 2018/0324935 A1
(43) Pub. Date: Nov. 8, 2018

(54) Wireless Diagnostic Management of Light Fixtures

(71) Applicant: Eaton Intelligent Power Limited, Dublin (IE)

(72) Inventors: Scott Peter Formel, Peachtree City, GA (US); Brittany Nichole Crowe, Newnan, GA (US); Paul Christopher Duckworth, Holland, MI (US); Todd Andrew Zeilinger, Holland, MI (US); James Moan, Fayetteville, GA (US)

(21) Appl. No.: 15/974,503

(22) Filed: May 8, 2018

Related U.S. Application Data
(60) Provisional application No. 62/503,236, filed on May 8, 2017.

(51) Int. Cl. H05B 37/03; G01R 31/44; G05B 23/02

(52) U.S. Cl. CPC H05B 37/036; F21S 8/06; G05B 23/0272; G01R 31/44

(57) ABSTRACT

A lighting system includes a plurality of light fixtures. Each light fixture includes a sensor for performing a test on the light fixture an generating test data. The light fixtures also include a hardware processor and a radio communication module. The radio communication module can communicate the test data to a mobile computing device or to a node. A diagnostic software application can receive the test data, identify a malfunctioning component, and order a replacement component.

### RELATED APPLICATIONS

The present application claims priority to U.S. Provisional Patent Application No. 62/503,236, filed May 8, 2017, and titled “Wireless Diagnostic Management of Light Fixtures,” the entire contents of which are incorporated herein by reference.

### TECHNICAL FIELD

The present disclosure relates generally to light fixtures and more particularly to systems, methods, and devices for managing a diagnostic system for light fixtures.

### BACKGROUND

The ability to efficiently test light fixtures, diagnose problems with the light fixtures, and address the problems so that the light fixtures operate properly is desirable. Certain current approaches to testing and diagnosing problems with light fixtures can be manually intensive in that a person must physically interact with each light fixture that is to be tested and diagnosed. In buildings and other structures with numerous light fixtures, the testing and diagnosing process can require significant time and resources. Testing and diagnosing of light fixtures is particularly important for emergency light fixtures. In some instances, local laws and codes require that emergency light fixtures be tested for proper operation on a regular basis and require the maintenance of records reflecting the testing of the emergency light fixtures. Systems and methods that can more efficiently manage the testing, diagnosing, and repair of light fixtures, as well as the associated record keeping, would be beneficial.

### SUMMARY

The present disclosure is directed to a wireless diagnostic system for light fixtures. In one example, a lighting system has at least one light fixture that includes a sensor, a hardware processor, and a radio communication module. The sensor can perform a test on the light fixture and generate test data. The hardware processor can receive the test data and provide the test data to the radio communication module for transmission to a mobile computing device. The mobile computing device can have a diagnostic software application that evaluates the test data, identifies any test data indicating a malfunctioning component, and can provide a prompt to order a replacement component for the malfunctioning component.

In another example, a lighting system can include a plurality of light fixtures, wherein each light fixture includes a sensor for performing a test on the light fixture, a hardware processor configured to receive the test data from the sensor, a short range radio communication module, and a mesh network radio communication module. The short range radio communication can communicate the test data to a nearby mobile computing device. The mesh network radio communication module can communicate with other mesh network radio communication modules located in other light fixtures or other electrical devices. The mesh network radio communication module can also communicate test data from multiple light fixtures to a node. A diagnostic software application can receive the test data gathered from the multiple light fixtures, evaluate the test data to identify malfunctioning components, and provide a prompt to order any needed replacement components.

In yet another example, a lighting system can include a plurality of light fixtures, wherein each light fixture includes a sensor for performing a test on the light fixture, a hardware processor configured to receive the test data from the sensor, a short range radio communication module, and a mesh network radio communication module. The short range radio communication can communicate the test data to a nearby mobile computing device. The mesh network radio communication module can communicate with other mesh network radio communication modules located in other light fixtures or other electrical devices. The lighting system can also include a wireless gateway comprising a gateway mesh network radio communication module for receiving the test data from the mesh network communication modules of the plurality of light fixtures. A diagnostic software application can receive the test data gathered from the multiple light fixtures, evaluate the test data to identify malfunctioning components, and provide a prompt to order any needed replacement components.

The foregoing are only non-limiting examples and these other embodiments will be described further in the following description and accompanying figures.

### BRIEF DESCRIPTION OF THE DRAWINGS

Reference will now be made to the accompanying drawings, which are not necessarily drawn to scale, and wherein:

FIG. 1 illustrates a system for managing diagnostics of light fixtures according to a first example embodiment;

FIG. 2A illustrates additional details of the components of the system for managing diagnostics of light fixtures according to the first example embodiment;

FIG. 2B illustrates a method of operation for the system of managing diagnostics of light fixtures according to the first example embodiment;

FIG. 3 illustrates a system for managing diagnostics of light fixtures according to a second example embodiment;

FIG. 4A illustrates additional details of the components of the system for managing diagnostics of light fixtures according to the second example embodiment;

FIG. 4B illustrates a method of operation for the system of managing diagnostics of light fixtures according to the second example embodiment;

FIG. 5 illustrates a system for managing diagnostics of light fixtures according to a third example embodiment;

FIG. 6A illustrates additional details of the components of the system for managing diagnostics of light fixtures according to the third example embodiment; and

FIG. 6B illustrates a method of operation for the system of managing diagnostics of light fixtures according to the third example embodiment.

The drawings illustrate only example embodiments and are therefore not to be considered limiting, as the disclosure may admit to other equally effective embodiments. The elements and features shown in the drawings are not necessarily to scale, emphasis instead being placed upon clearly illustrating the principles of the example embodiments. Additionally, certain dimensions or positions may be exaggerated to help visually convey such principles. In the drawings, reference numerals designate like or corresponding, but not necessarily identical, elements.

### DETAILED DESCRIPTION OF EXAMPLE EMBODIMENTS

In the following paragraphs, wireless diagnostic management systems for light fixtures will be described in further detail by way of example with reference to the attached drawings. In the description, well known components, methods, and/or processing techniques are omitted or briefly described so as not to obscure the invention.

For any figure shown and described herein, one or more of the components may be omitted, added, repeated, and/or substituted. Accordingly, embodiments shown in a particular figure should not be considered limited to the specific arrangements of components shown in such figure. Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure.

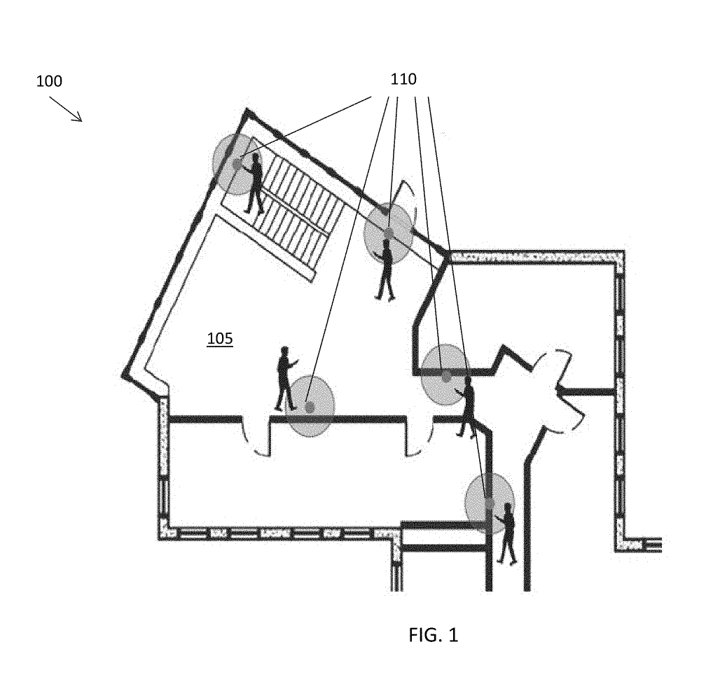

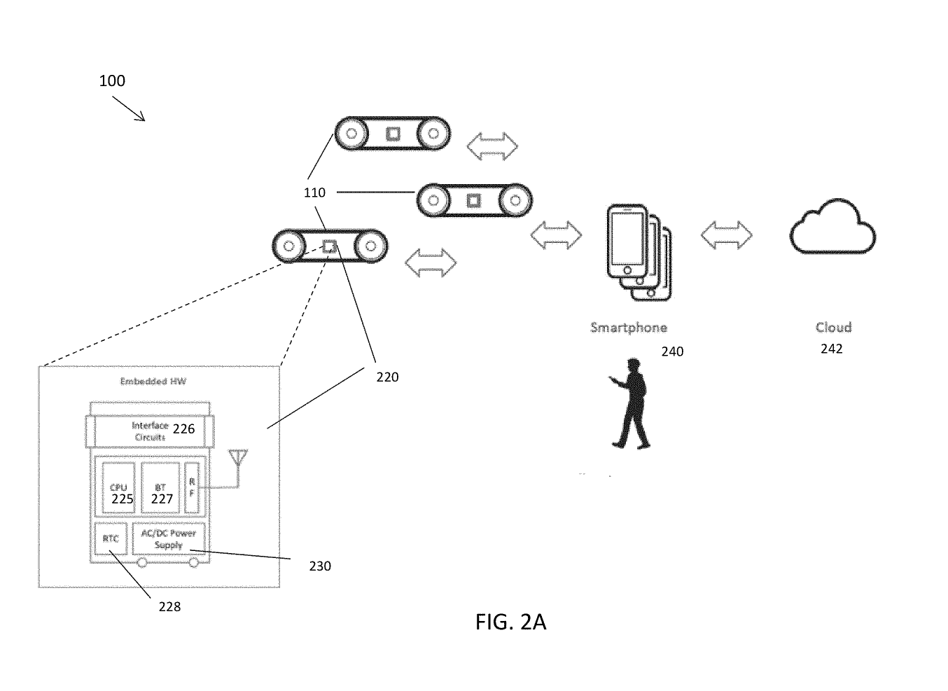

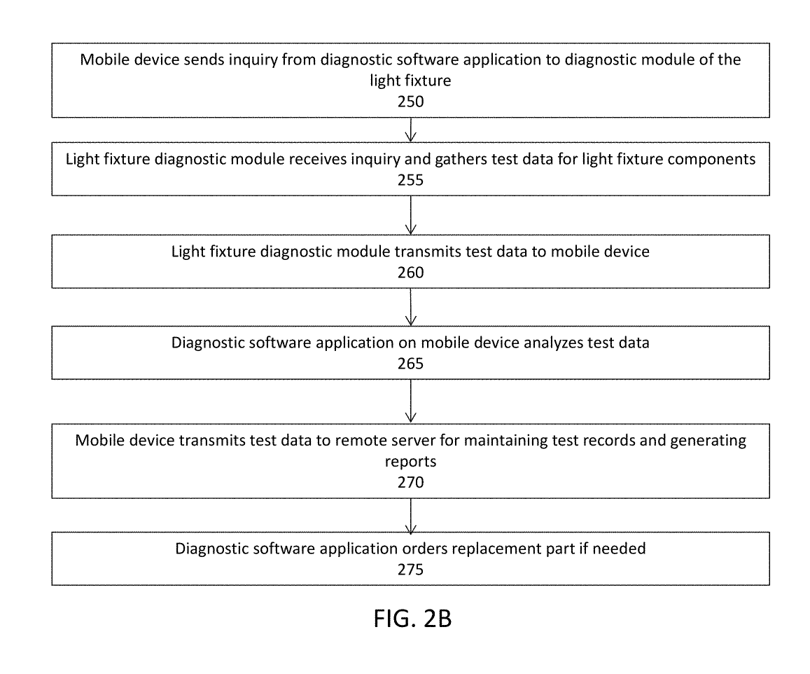

Turning now to the drawings, FIGS. 1, 2A, and 2B illustrate a first example embodiment of a system for wirelessly managing the diagnostics of a lighting system. As illustrated in FIGS. 1 and 2A, a building 105 can have a lighting system 100 with multiple light fixtures 110 distributed throughout the building 105. The light fixtures 110 may be emergency light fixtures or emergency exit signs required to comply with safety regulations or the light fixtures 110 may include non-emergency light fixtures used for ordinary illumination. Each light fixture 110 typically comprises a light source and a power supply that receives power from a power source and conditions the power for supply to the light source. In accordance with the embodiments described herein, each light fixture 110 also can comprise a diagnostic module 220 incorporated into each light fixture 110 for managing the testing of each light fixture 110. The diagnostic module 220 can comprise one or more sensors represented as interface circuits 226 for testing the proper functioning of the light fixture 110. In alternate embodiments, a single sensor can test a plurality of light fixtures, for example, a sensor that tests a power supply providing power to multiple light fixtures. The sensors may test the proper functioning of the light source within the light fixture, a power supply, and a back-up power supply such as a battery, as examples.

In connection with the testing, if the sensors detect that one or more components of the light fixture are not operating properly, the test data indicating the malfunctioning component can be provided via a hardware processor 225 to a radio communication module 227 that is a part of the diagnostic module 220 installed in the light fixture. The wireless radio communication module 227 can use one or more known radio communication protocols. For example, the radio communication module 227 may be designed for short range communications (e.g., 5 to 50 feet) using a protocol such as Bluetooth or Bluetooth Low Energy. Each light fixture can also comprise a clock 228 for scheduling regular testing so that scheduled testing does not disrupt routine activities at the building. The diagnostic module 220 can have its own power supply 230 that provides power to the components of the diagnostic module 220, or alternatively, the diagnostic module can draw power from a power supply serving the light source or other components of the light fixture.

Referring to FIG. 2B, an example method describing the operation of the lighting system 100 is provided. It should be understood that the method illustrated in FIG. 2B is a non-limiting example and that in other implementations one or more steps can be added or removed from the method shown in FIG. 2B. The example method begins with a mobile device 240 sending an inquiry from a diagnostic software application installed on the mobile device 240 in step 250. The inquiry is sent from the mobile device 240 to a light fixture 110. In step 255, the light fixture 110 receives the inquiry from the mobile device 240 and gathers test data for the light fixture components. For example, as described previously, the test data may be collected from sensors, such as the interface circuits 226, stored by the processor 225 in a memory associated with the radio communication module 227. In step 260, the radio communication module 227 of the light fixture 110 can transmit the test data to the mobile computing device 260. In this way, a user with a mobile computing device, such as smart telephone or a tablet, can pass near each light fixture 110 and collect test data from that light fixture 110. Using a mobile device to collect the test data from each light fixture is an improvement over prior art techniques that may have required additional equipment for testing a light fixture, may have required scheduling of personnel to perform the testing, and may have required a person to examine or manipulate portions of the light fixture.

Continuing with the example method shown in FIG. 2B, in step 265, the diagnostic software application operating on the mobile computing device 240 can analyze the collected test data to identify any malfunctioning components and identify the location of the light fixture 110 with the malfunctioning components. Information identifying the light fixture 110, such as a serial number and/or location may be included with the test data received at the mobile computing device 240. Alternatively, the mobile computing device 240 can be used to identify the light fixture 110 in any of a variety of ways including scanning an identifying code on the light fixture or using the mobile computing device's GPS system to identify the location of the light fixture. In step 270, the mobile computing device 240 transmits the collected test data to one or more of a local or remote computing system for storing and maintaining test records for the light fixtures. For example, a remote computing system represented by the cloud computing system 242 in FIG. 2A can receive the test data from the mobile computing device 240. The local or remote computing system can be a part of or in communication with a building management system for the building in which the light fixtures are located. The stored test records can later be retrieved and used to generate reports that satisfy reporting requirements set by the owner or manager of the facility or by local laws or regulations. In alternate embodiments, there may be no need for a local or remote computing system and, instead, the test records can be stored and the reports generated from the mobile computing device 240.

If the analysis of the test data indicates a component of the light fixture 110 is malfunctioning, in step 275, the diagnostic software application can identify a component of the light fixture that should be replaced and prompt either the user of the mobile computing device 240 or another user to order the needed component. The order for the needed component can be submitted from the mobile computing device 240 or the local or remote computing system to a vendor of the component so that the malfunctioning light fixture can be promptly repaired. Once the light fixture 110 has been repaired, the records stored in the local or remote computing system can also be updated to reflect that the repair has been completed.

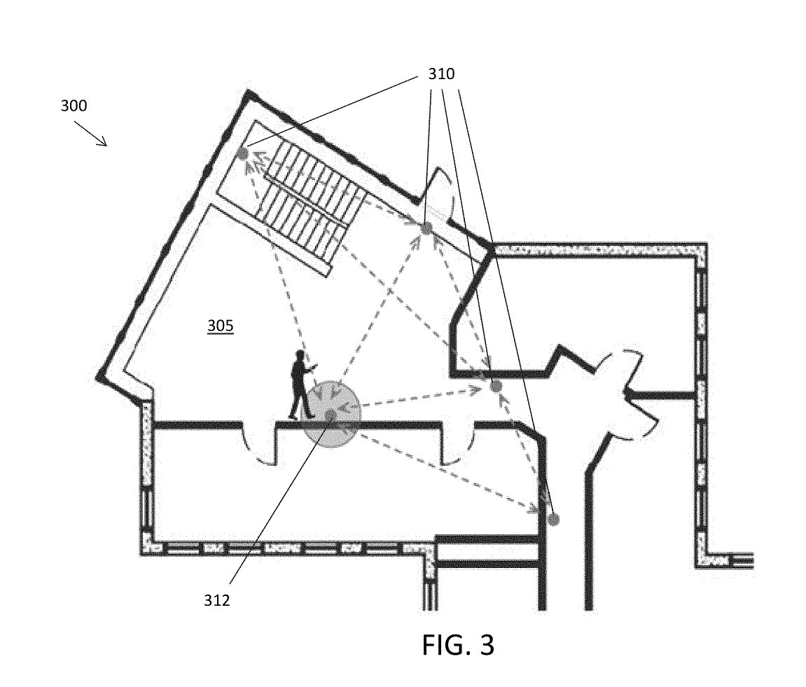

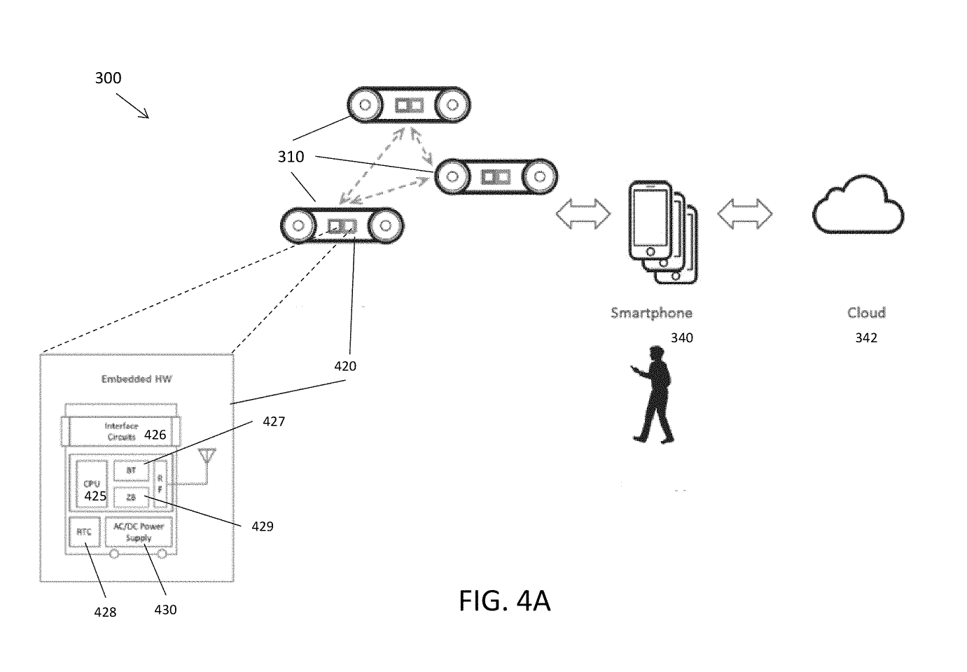

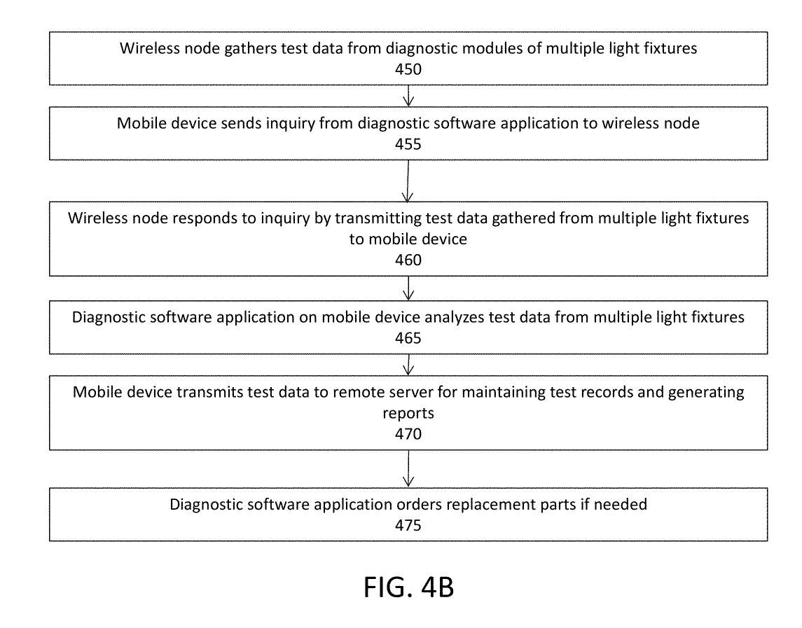

Referring now to FIGS. 3, 4A, and 4B, a second example embodiment of a wireless diagnostic management system is illustrated. The second example is similar to the first example described in connection with FIGS. 1-2B, except that the second example is designed for environments with significantly more light fixtures than the first example. Components in the second example that are analogous to components in the first example have the same last two reference numbers as the components in the first example and a detailed description of those analogous components in the second example will not be repeated. Lighting system 300 of the second example is different from lighting system 100 of the first example in that the diagnostic module 420 in each light fixture 310 can be equipped with both a short range radio communication module 427, such as a Bluetooth protocol radio, as well as a mesh network radio communication module 429, such a radio that communicates using the Zigbee protocol or another known mesh network protocol. The mesh network radio communication module 429 in each of the light fixtures 310 permits multiple light fixtures to communicate test data among each other thereby simplifying the collection of test data from many more light fixtures 310. A further difference in lighting system 300 is the presence of node 312 for receiving test data via wireless communications from multiple light fixtures 310. A user with a mobile computing device 340 can collected the test data associated with the multiple light fixtures 310 from the single node 312 thereby further simplifying the collection of test data from a large number of light fixtures. In certain embodiments, a few nodes can be dispersed throughout a building with each node assigned to collect test data from a group of light fixtures via wireless communications. A person with a mobile computing device 340 can collect the test data for multiple light fixtures from each node.

Referring to FIG. 4B, an example method describing the operation of lighting system 300 is provided. Beginning with step 450, the node 312 collects test data from diagnostic modules 420 located in multiple light fixtures 310. In step 455, the mobile computing device 340 sends an inquiry for test data from a diagnostic software application installed on the mobile computing device. In step 460, the node 312 responds by transmitting the test data gathered from multiple light fixtures 310 to the mobile computing device 340. In step 465, the diagnostic software application operating on the mobile computing device 340 can analyze the collected test data to identify any malfunctioning components and, if needed, identify the location of the light fixture with the malfunctioning component. In an alternative embodiment, the diagnostic software application may be operating on a remote cloud computing system 342 that receives the test data from the mobile computing device 340 for analysis. Regardless of whether the analysis is performed locally or remotely, in step 470, the mobile computing device 340 can transmit the test data to one or more of a local or remote computing system for maintaining test records and generating reports. Lastly, in step 475, the diagnostic software application can order a replacement component for a malfunctioning component if appropriate.

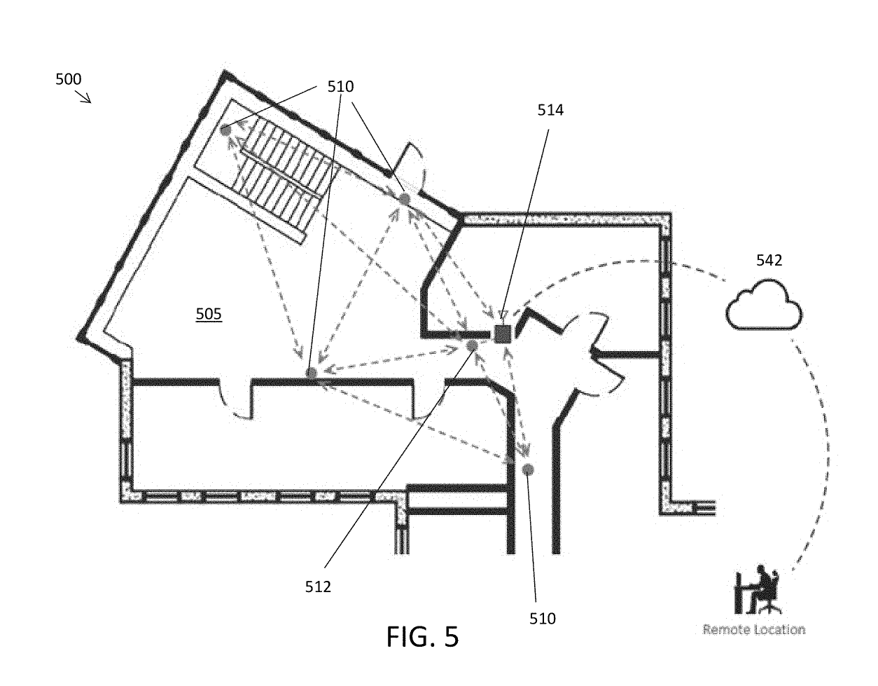

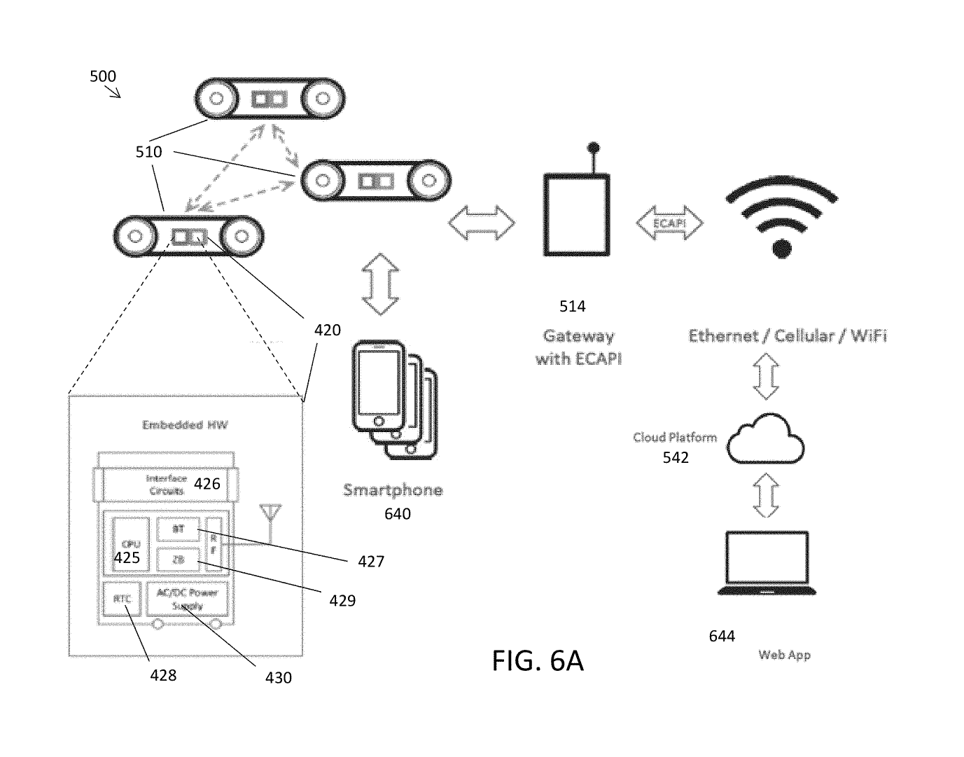

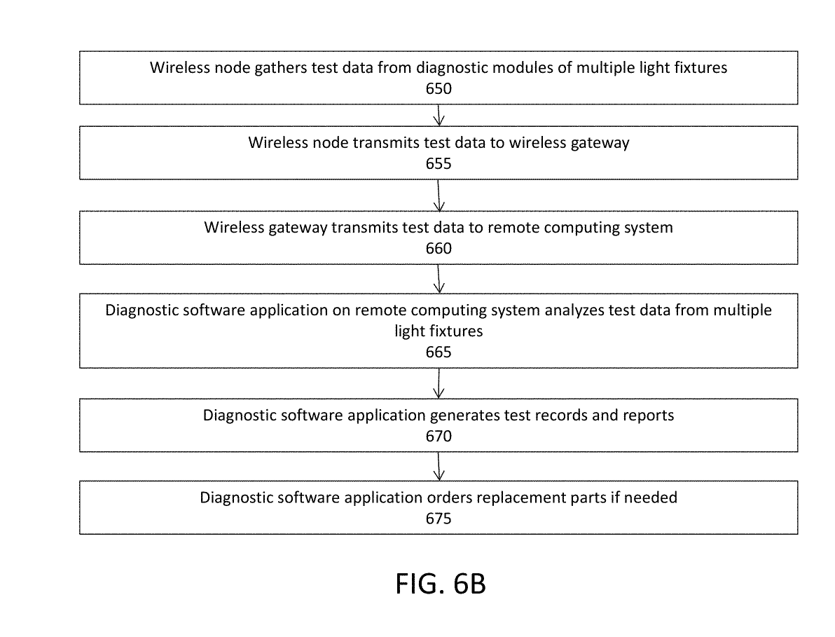

Referring now to FIGS. 5, 6A, and 6B, a third example embodiment of a wireless diagnostic management system is illustrated. The third example is similar to the previous examples, except that the third example is designed for environments with even more light fixtures, such as a facility with 1,000 or more light fixtures. Components in the third example that are analogous to components in the first or second examples have the same reference numbers or the same last two reference numbers as the components previously described in connection with FIGS. 1-4B and a detailed description of those analogous components will not be repeated. As with the lighting system 300 of the second example described in connection with FIGS. 3-4B, the diagnostic module 420 in each fixture 510 of lighting system 500 can be equipped with both a short range radio communication module 427, such as a Bluetooth protocol radio, as well as a mesh network radio communication module 429, such as a radio that communicates using the ZigBee protocol or another known mesh network protocol. As with lighting system 300, using a mesh network radio communication module 429 in each light fixture 510 of lighting system 500 permits multiple light fixtures 510 to communicate test data among each other thereby simplifying the collection of test data from a large number of light fixtures. Optionally, the lighting system 500 can also use a node 512 for gathering test data from a group of light fixtures 510 in an area.

The lighting system 500 of the third example is unique in that the test data from each light fixture is communicated over the wireless mesh network to a wireless gateway 514. The wireless gateway The wireless gateway 514 can be part of a building management system operated by the building manager. The wireless gateway 514 can then transmit the collected test data for the light fixtures 510 to a remote computing system 542 via any of a variety of communication networks, such as an Ethernet, WiFi, or cellular network. The remote computing system 542 can manage, store, and analyze the test records. As in the previous examples, a diagnostic software application running on a remote computing device 644 can analyze the collected test data, identify malfunctioning components and the locations of the light fixtures with the malfunctioning components, and prompt an order for replacement components. As with the previous examples, the stored test records can also be retrieved from the remote computing system to generate required reports relating to the testing, maintenance, and repair of the light fixtures.

Referring to FIG. 6B, an example method describing the operation of lighting system 500 is provided. Beginning with step 650, the node 512 collects test data from diagnostic modules 420 located in multiple light fixtures 510. The node 512 transmits the test data collected from multiple light fixtures 510 to the wireless gateway 514 in step 655. Alternatively, system 500 can be implemented without nodes and diagnostic modules 420 in the light fixtures 510 can transmit the test data to the wireless gateway 514. In step 660, the wireless gateway 514 can transmit the test data collected from the light fixtures 510 to the remote computing system 542.

The remote computing system 542 can include a workstation 544 on which the diagnostic software application is running. In step 665, the diagnostic software application can analyze the test data received from the wireless gateway 514 and, in step 670, the diagnostic software application can generate test records and reports using the received test data. For example, the generated reports can be used to comply with regulations showing that the emergency lights in building 505 have been tested and are working properly. If test data indicates that a component of a light fixture 510 is not operating properly, the diagnostic software application can use the test data and the identifier for the light fixture from which the test data was collected to order a replacement component and schedule a repair for the replacement component to be installed in the identified light fixture.

The embodiment illustrated in FIGS. 5, 6A, and 6B can be modified so that the wireless gateway 514 can be combined with the remote computing system 542. Additionally, in yet another embodiment, the wireless gateway 514 can be eliminated and the diagnostic module 420 can communicate the test data to a remote computing system via one of the radio communication modules.

The example embodiments described herein are representative and, in alternative embodiments, certain features, elements, and/or steps may be added or omitted. Additionally, modifications to aspects of the embodiments described herein may be made by those skilled in the art without departing from the spirit and scope of the present disclosure defined in the following claims, the scope of which are to be accorded the broadest interpretation so as to encompass modifications and equivalent structures.

What is claimed is:

1. A lighting system, comprising:
a light fixture;
at least one sensor installed in the light fixture, the at least one sensor for performing a test of the operation of the light fixture and generating test data;
a hardware processor installed in the light fixture, the hardware processor configured to receive the test data from the at least one sensor;
a radio communication module located within the light fixture and in communication with the hardware processor, the radio communication module for communicating the test data wirelessly to a mobile computing device; and
a diagnostic software application that executes on the mobile computing device, the diagnostic software application comprising instructions for evaluating the test data, identifying a malfunctioning component of the light fixture, and providing a prompt to order a replacement component.

2. The lighting system of claim 1, further comprising a computing system for receiving the test data from the mobile computing device and storing the test data.

3. The lighting system of claim 2, wherein the computing system is a building management system.

4. The lighting system of claim 2, wherein the diagnostic software application is also stored on the computing system.

5. The lighting system of claim 2, wherein the computing system stores records of light fixtures that have been repaired.

6. The lighting system of claim 1, wherein the computing system can generate reports containing the test data.

7. The lighting system of claim 1, wherein the diagnostic software application can transmit an instruction to the radio communication module to schedule the test performed on the light fixture using a clock located within the light fixture.

8. A lighting system, comprising:
a plurality of light fixtures, each light fixture of the plurality of light fixtures comprising:
a sensor for performing a test on a light fixture in which the sensor is installed and generating test data;
a hardware processor configured to receive the test data from the sensor;
a short range radio communication module in communication with the hardware processor, the short range radio communication module for communicating the test data to a mobile computing device; and
a mesh network radio communication module in communication with the hardware processor, the mesh network radio communication module for communicating the test data to other mesh network radio communication modules; and
a diagnostic software application that comprises instructions for evaluating the test data, identifying a malfunctioning component among the plurality of light fixtures, and providing a prompt to order a replacement component.

9. The lighting system of claim 8, further comprising:
a node, the node comprising a node mesh network radio communication module for receiving the test data from the plurality of light fixtures.

10. The lighting system of claim 9, wherein the node is located within a node light fixture.

11. The lighting system of claim 9, wherein the diagnostic software application executes on the mobile computing device and receives the test data via a wireless transmission from the node.

12. The lighting system of claim 8, wherein the test data comprises an identifier for the light fixture from which the test data was retrieved.

13. The lighting system of claim 8, wherein the diagnostic software application executes on a remote computing device and receives the test data via a wireless transmission from the mobile computing device.

14. The lighting system of claim 8, wherein the diagnostic software application can transmit an instruction to the light fixture to schedule the test performed on the light fixture using a clock located within the light fixture.

15. A lighting system, comprising:
a plurality of light fixtures, each light fixture of the plurality of light fixtures comprising:
a sensor for performing a test on a light fixture in which the sensor is installed and generating test data;
a hardware processor configured to receive the test data from the sensor;
a short range radio communication module in communication with the hardware processor, the short range radio communication module for communicating the test data to a mobile computing device; and
a mesh network radio communication module in communication with the hardware processor, the mesh network radio communication module for communicating the test data to other mesh network radio communication modules;
a wireless gateway comprising a gateway mesh network radio communication module for receiving the test data from the mesh network communication modules of the plurality of light fixtures; and
a diagnostic software application that comprises instructions for evaluating the test data, identifying a malfunctioning component among the plurality of light fixtures, and providing a prompt to order a replacement component.

16. The lighting system of claim 15, further comprising a remote computing system on which the diagnostic software application executes, the remote computing system receiving the test data from the wireless gateway.

17. The lighting system of claim 16, wherein the remote computing system and the wireless gateway are components of a building management system.

18. The lighting system of claim 15, wherein the test data comprises an identifier for the light fixture from which the test data was retrieved.

19. The lighting system of claim 16, wherein the remote computing system stores records of light fixtures that have been repaired.

20. The lighting system of claim 15, wherein the diagnostic software application can schedule the test performed on each light fixture of the plurality of light fixtures.
